(19) United States
(12) Patent Application Publication
(10) Pub. No.: US 2007/0121398 A1
(43) Pub. Date: May 31, 2007

(54) Memory controller capable of handling precharge-to-precharge restrictions

(76) Inventors: Mark D. Bellows, Rochester, MN (US); Paul A. Ganfield, Rochester, MN (US); Ryan A. Heckendorf, Rochester, MN (US)

Correspondence Address: DILLON & YUDELL LLP, 8911 N. CAPITAL OF TEXAS HWY.,, SUITE 2110, AUSTIN, TX, 78759, US

(21) Appl. No.: 11/289,053

(22) Filed: Nov. 29, 2005

(51) Int. Cl. G11C 7/00

(52) U.S. Cl. 365/203

(57) ABSTRACT

A memory controller capable of handling precharge-to-precharge restrictions is disclosed. Upon commencement of a write operation, the location of the corresponding write precharge command is tracked from a timing standpoint. A determination is then made as to whether or not a subsequent read precharge command will collide with any pending write precharge command. In a determination that a subsequent read precharge command will collide with any pending write precharge command, the issuance of this read precharge command is delayed in order to avoid any collision; also, a specific time interval between this read precharge command and subsequent read precharge commands is maintained.

### BACKGROUND

1. Technical Field

The present invention relates to memory controllers in general. More particularly, the present invention relates to extreme data rate (XDR) memory controllers. Still more particularly, the present invention relates to an XDR memory controller capable of handling precharge-to-precharge restrictions.

2. Description of Related Art

A memory controller is typically utilized to regulate access requests on memory devices from various requesting devices. After receiving an access request along with address and control information from a requesting device, the memory controller decodes the address information into bank, row and column addresses. The memory controller then sends address and control signals to the appropriate memory devices for performing the requested memory operation, such as a read or write operation. For a read operation, the memory controller sends the read command and then returns the read data retrieved from the memory devices to the requesting device. For a write operation, the memory controller sends the write data to the memory devices along with the write command.

When performing read and write operations, a memory controller is responsible for generating an appropriate sequence of control signals for accessing the desired addresses within the memory devices. The sequence of control signals for an operation typically involves activating (or opening) a row of a bank within the memory devices, then writing to or reading from the selected columns in the activated row, and finally precharging (or closing) the activated row. The precharge associated with a write operation is called a write precharge and the precharge associated with a read operation is called a read precharge.

In order to maximize bandwidth, a memory controller typically issues read operations and write operations in streams. According to the extreme data rate (XDR) dynamic random access memory (DRAM) specification promulgated by Rambus Incorporated of Los Altos, Calif., a new read or write operation can be started every fourth command cycle (i.e., row-to-row time=4). In addition, the precharge-to-precharge time between different bank sets, t_{PP-D}, is the minimum time interval between a precharge command issued to the odd bank set and a precharge command issued to the even bank set (or vice versa), and the precharge-to-precharge time, t_{PP}, is the minimum precharge-to-precharge time between same bank sets. During the transition from a write operation stream to a read operation stream, if the operations are going to different bank sets (known as Early Read After Write), a read precharge command has the possibility of conflicting with a write precharge command. The read precharge command will tend to collide with the write precharge command when a write operation stream is crossing to a read operation stream, which violates t_{PP-D, min} of 1. The present disclosure provides an XDR memory controller that is capable of preventing the above-mentioned collision when issuing consecutive precharge commands.

### SUMMARY

In accordance with a preferred embodiment of the present invention, upon commencement of a write operation, the location of the corresponding write precharge command is tracked from a timing standpoint. A determination is then made as to whether or not a subsequent read precharge command will collide with any pending write precharge command. In a determination that a subsequent read precharge command will collide with any pending write precharge command, the issuance of this read precharge command is delayed in order to avoid any collision; also, a specific time interval between this read precharge command and subsequent read precharge commands is maintained.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a block diagram of an information handling system including an extreme data rate (XDR) memory subsystem in which a preferred embodiment of the present invention is incorporated;

FIG. 2 is a block diagram of the logic within the memory controller from FIG. 1 for handling precharge-to-precharge restrictions when issuing consecutive precharge commands, in accordance with a preferred embodiment of the present invention;

FIG. 3 is a timing diagram of an example of issuing multiple precharge commands over a time period from T₁ to T₄₅; and

FIG. 4 graphically illustrates an example of loading a write precharge scoreboard within the logic from FIG. 2, according to the timing diagram of FIG. 3.

### DETAILED DESCRIPTION OF AN ILLUSTRATIVE EMBODIMENT

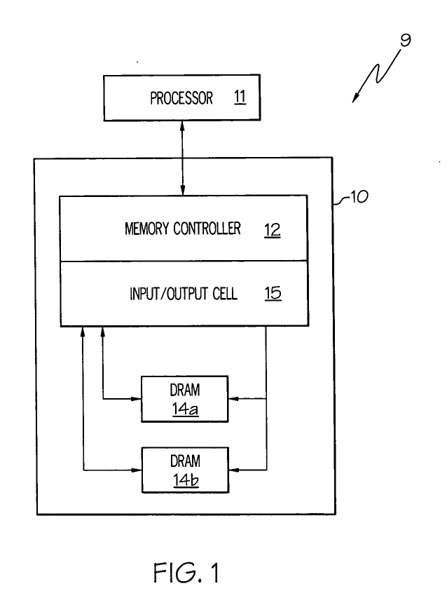

Referring now to the drawings and in particular to FIG. 1, there is depicted a block diagram of an information handling system including an extreme data rate (XDR) memory subsystem in which a preferred embodiment of the present invention is incorporated. While a particular number and arrangement of elements have been illustrated with respect to information handling system 9 of FIG. 1, it should be appreciated that embodiments of the present invention are not limited to systems having any particular number, type, or arrangement of components and so many encompass a wide variety of system types, architectures, and form factors (e.g., network elements or nodes, personal computers, workstations, servers, information appliances, personal digital assistants, or the like). Information handling system 9 of the illustrated embodiment includes a processor 11 coupled to a memory subsystem 10 utilizing a bus or other communication medium. While memory subsystem 10 has been depicted as including random access memory (RAM) specifically, any of a number of system memory-type storage elements including but not limited to, read-only memory (ROM), flash memory, and cache may be utilized in alternative embodiments.

Similarly, while information handing system 9 has been depicted as including only processor 11 and memory subsystem 10, in alternative embodiments of the present invention information handling system 9 may further comprise an input/output (I/O) interface (not shown) coupled to one or more of processor 11 and memory subsystem 10 in order to communicatively couple one or more I/O devices (not shown) to information handling system 9. Exemplary I/O devices may include traditional I/O devices such as keyboards, displays, printers, cursor control devices (e.g., trackballs, mice, tablets, etc.), speakers, and microphones; storage devices such as fixed or “hard” magnetic media storage devices, optical storage devices (e.g., CD or DVD ROMs), solid state storage devices (e.g., USB, Secure Digital SD™, CompactFlash™, MMC, or the like), removable magnetic medium storage devices such as floppy disks and tape, or other storage devices or mediums; and wired or wireless communication devices or media (e.g., communication networks accessed via modem or direct network interface).

As shown, an XDR memory subsystem 10 includes an XDR memory controller 12 and an XDR input/output cell 15 along with two DRAM devices 14a-14b. Input/output cell 15 provides the physical layer interface between memory controller 12 and an XDR channel, and can be viewed as a serializer/deserializer for the purpose of the present invention. Details on input/output cell 15 can be found in XIO specifications promulgated by Rambus Incorporated of Los Altos, Calif., the pertinent of which is incorporated by reference herein. XDR memory subsystem 10 is shown to be connected to a processor 11 by a bus, such as in a data processing or “information handling” system, as is well-known to those skilled in the art. DRAM devices 14a-14b are preferably XDR DRAM devices. Details on XDR DRAM devices 14a-14b can be found in XDR DRAM specifications promulgated by Rambus7, the pertinent of which is incorporated by reference herein.

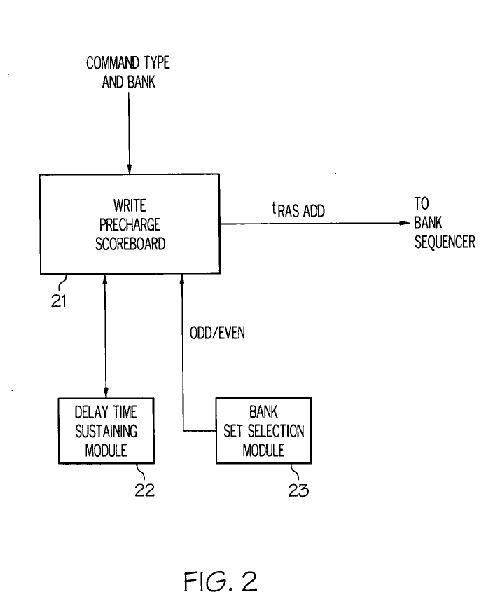

With reference now to FIG. 2, there is depicted a block diagram of the logic within memory controller 12 for handling precharge-to-precharge restrictions when issuing consecutive precharge commands, in accordance with a preferred embodiment of the present invention. As shown, the logic includes a write precharge scoreboard 21 for tracking the location of each pending write precharge command from a timing standpoint based on write operations that have been started but are not yet complete. Write precharge scoreboard 21 is also used to determine whether or not a subsequent read precharge command will collide with a pending write precharge command. If a collision between a write precharge command and a subsequent read precharge command is expected, write precharge scoreboard 21 provides an appropriate delay time t_{RAS} Add to the subsequent read precharge command to delay the issuance of the read precharge command such that a collision between the write precharge command and the read precharge command is avoided. The addition of a delay time t_{RAS} Add means that memory controller 12 will temporarily increase the row assert time, which delays the read precharge command by one, two or three command cycles depending on the value of delay time t_{RAS} Add.

Delay time t_{RAS} Add with a value of one will be added to a subsequent read precharge command if the issuance of the read command would otherwise cause it to collide with a write precharge command. Delay time t_{RAS} Add value becomes a two if the issuance of a second read operation after an Early Read transition would otherwise cause an associated second read precharge command to collide with a write precharge command. Similarly, delay time t_{RAS} Add value becomes a three if the issuance of a third read operation after an Early Read transition would otherwise cause an associated third read precharge command to collide with a write precharge command.

The maximum value of delay time t_{RAS} Add is preferably three because values of four or greater will start interacting with future write precharge commands. If a fourth read operation attempts to start when the t_{RAS} Add delay time value is already at three, then the new read operation is stalled one command cycle so that the fourth read operation will be issued with a t_{RAS} Add delay time value of no more than three. After the last write precharge command in write precharge scoreboard 21 has been analyzed, the value of delay time t_{RAS} Add is maintained if the next read command is to the same bank set such that the precharge-to-precharge time for same bank sets (i.e., t_{PP}) is met. Otherwise, the value of delay time t_{RAS} Add is reduced by one after each passing command cycle until the value of delay time t_{RAS} Add returns to zero.

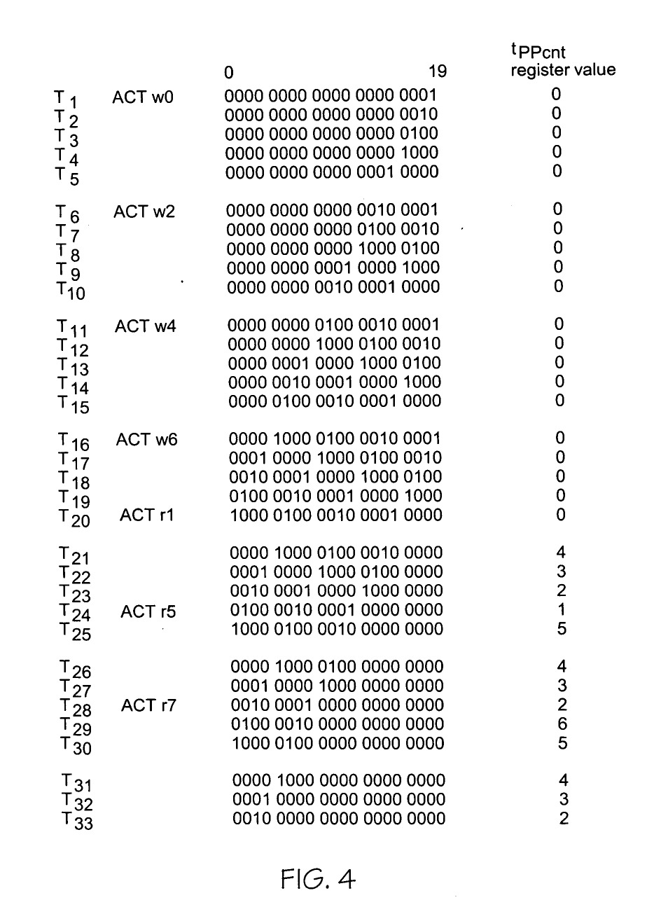

The contents of the tracking mechanism (write precharge scoreboard) are shown in FIG. 4. The three most significant bits of write precharge scoreboard 21 are compared against t_{PPcnt}, and t_{PPcnt} is a 3-bit value stored in a register that decrements each command cycle (0 is the minimum value). This comparison is needed so that the read precharge commands maintain t_{PP} and t_{PP-D}. If one read precharge command moves by one cycle, subsequent read precharge commands may also need to move by one cycle. This comparison determines the value of delay time t_{RAS} Add for the current read precharge command. If the t_{PPcnt} value is 0 and the most significant bit of write precharge scoreboard 21 is a “1,” then the value of delay time t_{RAS} Add will be a one. If the t_{PPcnt} value is 1 and the two most significant bits of write precharge scoreboard 21 are “01,” then the value of delay time t_{RAS} Add will be a two. If the t_{PPcnt} value is 2 and the three most significant bits of write precharge scoreboard 21 are “001,” then the value of delay time t_{RAS} Add will be a three. Otherwise, the value of delay time t_{RAS} Add is t_{PPcnt}. If t_{PPcnt} is greater than 3, and the issuance of a command is pending, that command will be stalled.

Upon commencement of a read operation, the t_{RAS} Add delay time value is sent to a bank sequencer (not shown) and to a delay time sustaining module 22. For the present embodiment, delay time sustaining module 22 first subtracts 1 and then adds 4 to the value of delay time t_{RAS} Add, and the sum is stored as the t_{PPcnt} value. Each cycle, the value of t_{PPcnt} is decremented by 1, reloaded from write precharge scoreboard 21 if there is a potential collision with a write precharge command, or loaded with the current value +4 if there is a read operation to the same bank set that is starting. The addition of a +4 maintains the t_{PP} spacing to the same bank set. A bank set selection module 23 is utilized to “remember” which bank set is the opposite bank set for the current read precharge command.

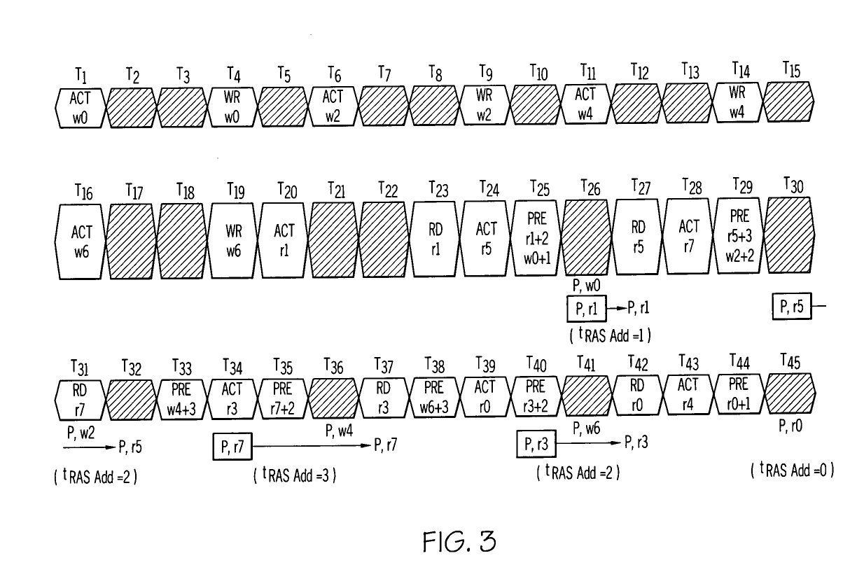

Referring now to FIG. 3, there is depicted a timing diagram of an example of issuing multiple precharge commands to a set of XDR DRAM devices, such as XDR DRAM devices 14a-14b from FIG. 1, over a time period from T₁ to T₄₅, in accordance with a preferred embodiment of the present invention. The XDR command packet stream shown in FIG. 3 is hypothetical and is only for the purpose of illustrating the present invention. As shown, each command packet is displayed inside a six-sided polygon. A precharge command packet may contain two precharge commands. Write operation command packets are denoted by w0, w2, w4 and w6, where 0, 2, 4 and 6 are bank numbers (e.g., banks 0, 2, 4, and 6 belong to the even bank set). Read operation command packets are denoted by r1, r3, r5 and r7, where 1, 3, 5, and 7 are bank numbers (e.g., banks 1, 3, 5, and 7 belong to the odd bank set).

XDR DRAM command packets shown in FIG. 3 include activates (i.e., ACT), column writes (i.e., WR), column reads (i.e., RD) and row precharges (i.e., PRE). In addition, row precharge command packets can be issued with dynamic offsets, which are denoted by +0, +1, +2, or +3. A dynamic offset enables a row precharge command to be executed within the DRAMs at a later time than the time at which it is issued, depending on the value of dynamic offset. Row precharge commands for two different bank sets and rows can be combined into a single packet, such as the command packet in time T₂₅, which means that r1 precharge command will execute in two cycles and w0 precharge command will execute in the next cycle.

The natural time and the actual time for a precharge command to be executed are indicated right below each corresponding command packet (outside the six-sided polygon). The natural time for a read precharge command is included inside a rectangular box, which denotes the time at which a read precharge command would have been executed naturally without the present invention. The actual time is located to the right of a rectangular box, which denotes the time at which a read precharge command will be executed according to the present invention. For example, the precharge command [P, r1] for r1 will be executed at time T₂₇ (instead of naturally executing at time T₂₆). For a write operation, the precharge command is not adjusted, so its location is noted without any boxes or arrows. For example, the precharge command [P, w0] for w0 will execute at time T₂₆.

At time T₂₀, the first read operation is started after a write stream. By this time, the memory controller has determined that the t_{RAS} of the first read operation will need to be extended by one. At time T₂₅, the read precharge command [P, r1] for read operation r1 started at T₂₀ that would have naturally been executed at time T₂₆ is moved forward by one cycle to time T₂₇ in order to meet the t_{PP-D}=1 requirement. At time T₂₉, the read precharge command [P, r5] for read operation r5 started at time T₂₄ that would have naturally been executed at time T₃₀ is moved forward by two cycles to time T₃₂ in order to meet both the t_{PP-D}=1 and t_{PP}=4 timing requirements.

At time T₃₅, the read precharge command [P, r7] for read operation r7 started at time T₂₈ that would have naturally been executed at time T₃₄ is moved forward by three cycles to T₃₇ in order to meet the t_{PP-D}=1 and t_{PP}=4 timing requirements. Since t_{PP, min}=4, once an adjustment to a precharge command is made, subsequent precharge commands to the same set of banks must take that adjustment into account.

At time T₄₀, the read precharge command [P, r3] for read operation r3 started at time T₃₄ that would have naturally been executed at time T₄₀ is moved by two cycles to T₄₂ in order to meet the t_{PP-D}=1 and t_{PP}=4 timing requirements. The above-mentioned precharge commands need to be moved because the write precharge commands [P, w0], [P, w2], [P, w4] and [P, w6] execute at the same time as the read precharge commands for the corresponding read commands otherwise would.

With reference now to FIG. 4, there is illustrated an example of loading write precharge scoreboard 21 (from FIG. 2) and the t_{PPcnt} register according to the timing diagram of FIG. 3. As shown, write precharge scoreboard 21 has a 20-bit location numbered from bit 0 to bit 19, although a different number of bits could be utilized. Each row in FIG. 4 represents the bits in the same location of write precharge scoreboard 21 being shifted to the left (i.e., from bit 19 towards bit 0) so that when it is time to interpret write precharge scoreboard 21, the locations of the write precharge commands are analyzed.

A write operation marks the location in which the write precharge command will execute minus the time from which a read precharge would have executed, had it been issued at this time. For the present embodiment, the marking is performed by injecting a “1” at bit 19 of write precharge scoreboard 21. The injection of a “1I” at bit 19 of write precharge scoreboard 21 occurs each time when a write operation is started, such as T₁, T₆, T₁₁ and T₁₆ in FIG. 4.

As mentioned earlier, the three most significant bits (i.e., bits 0-2) of write precharge scoreboard 21, together with the t_{PPcnt} value determine the value of t_{RAS} Add. When a read operation starts:

a. if bits 0 to 2 of the scoreboard are all zeros, then t_{RAS} Add=t_{PPcnt}

b. if bit 0 of the scoreboard is a “1” and t_{PPcnt}=0, then t_{RAS} Add=1

c. if bit 1 of the scoreboard is a “1” and t_{PPcnt}=1, then t_{RAS} Add=2

d. if bit 2 of the scoreboard is a “1” and t_{PPcnt}=2, then t_{RAS} Add=3

e. if t_{PPcnt} is 3 or more, wait for t_{PPcnt} to be 2 or less before starting the operation and re-evaluate if case (a), (b), (c), (d) or (f) applies

f. if none of the above, then t_{RAS} Add=t_{PPcnt}

For example, at T₂₀, bit 0 of write precharge scoreboard 21 has a “1” and a read operation has been started, thus, the t_{RAS} Add value becomes 1. In each cycle from T₂₁-T₂₄, the t_{PPcnt} value decreases by one per cycle, i.e., from 4 at T₂₁ to 1 at T₂₄.

At T₂₄, bit 1 of write precharge scoreboard 21 has a “1” and a read operation has been started, thus, the t_{RAS} Add value becomes 2. In each cycle from T₂₅-T₂₈, the t_{PPcnt} value decreases by one per cycle, i.e., from 5 at T₂₅ to 2 at T₂₈.

At T₂₈, bit 2 of write precharge scoreboard 21 has a “1” and a read operation has been started, thus, the t_{RAS} Add value becomes 3. In each cycle from T₂₉-T₃₃, the t_{PPcnt} value decreases by one per cycle, i.e., from 6 at T₂₉ to 2 at T₃₃.

Once the value of t_{RAS} Add has been calculated (either a 0, 1, 2 or 3), the operation and its associated t_{RAS} Add are handed off to a bank sequencer (not shown). The bank sequencer uses the value to set counters for issuing the precharge command at the appropriate time, and for signaling other units that a bank in a bank set will be available 0, 1, 2 or 3 cycles later than normal.

As has been described, the present invention provides an XDR memory controller capable of handling precharge-to-precharge restrictions when issuing precharge commands. By knowing ahead of time that t_{PP} and t_{PP-D} timing requirements will not be violated, the bank sequencer within the memory controller simply sets counters instead of looking across all bank sequencers that are running and dynamically altering the issuance of precharge commands. Also, by realizing how much the effective t_{RAS} will be increased (i.e., t_{RAS} Add), the command issuing logic knows exactly when to signal to other units that a specific bank is available. Knowing which banks are available and when is important for optimizing performance and for correct functionality.

While the invention has been particularly shown and described with reference to a preferred embodiment, it will be understood by those skilled in the art that various changes in form and detail may be made therein without departing from the spirit and scope of the invention.

What is claimed is:

1. A method for a memory controller to handle precharge-to-precharge restrictions when issuing precharge commands, said method comprising:
upon starting a write operation, determining the location of a write precharge command for said write operation from a timing standpoint;
determining whether or not a timing parameter violation between said write precharge command and a subsequent read precharge command is to be expected; and
in response to a determination that a timing parameter violation between said write precharge command and a subsequent read precharge command is expected, delaying the execution of said subsequent read precharge command to avoid a potential timing parameter violation.

2. The method of claim 1, wherein said determining utilizes a write precharge scoreboard.

3. The method of claim 1, wherein said delaying further includes maintaining a specific time distance between said subsequent read precharge command and a next read precharge command.

4. The method of claim 3, wherein said delaying is accomplished by adding an appropriate time delay, t_{RAS} Add value, to the effective t_{RAS} timing parameter.

5. The method of claim 4, wherein said delaying includes increasing a row assert time for a read operation related to said subsequent read precharge command, which in turn delays said subsequent read precharge command by one, two, or three cycles depending on said time delay t_{RAS} Add value.

6. The method of claim 4, wherein said time delay t_{RAS} Add value is determined by comparing the three most significant bits of said write precharge scoreboard to a current t_{PPcnt} value.

7. The method of claim 4, wherein a time delay t_{RAS} Add value of one is added to a subsequent read precharge command if the start of a read operation will cause a subsequent read precharge command to collide with a write precharge command.

8. The method of claim 7, wherein said time delay t_{RAS} Add value becomes a two if the start of a second read operation will cause an associated second read precharge command to collide with the write precharge command.

9. The method of claim 8, wherein said time delay t_{RAS} Add value becomes a three if the start of a third read operation will cause an associated third read precharge command to collide with the write precharge command.

10. The method of claim 1, wherein said memory controller is an extreme data rate memory controller.

11. A memory controller capable of handling precharge-to-precharge restrictions when issuing precharge commands, said memory controller comprising:
means for determining, upon starting a write operation, the location of a write precharge command for said write operation from a timing standpoint;
means for determining whether or not a timing parameter violation between said write precharge command and a subsequent read precharge command is to be expected; and
in response to a determination that a timing parameter violation between said write precharge command and a subsequent read precharge command is to be expected, means for delaying an issuance of said subsequent read precharge command to avoid any potential timing parameter violation.

12. The memory controller of claim 11, wherein said determining means is a write precharge scoreboard.

13. The memory controller of claim 11, wherein said delaying means further includes means for maintaining a specific time distance between said subsequent read precharge command and a next read precharge command.

14. The memory controller of claim 13, wherein said delaying means includes means for adding an appropriate time delay value, t_{RAS} Add, to the effective t_{RAS} timing parameter.

15. The memory controller of claim 14, wherein said delaying means includes means for increasing a row assert time for a read operation related to said subsequent read precharge command, which in turns delays said subsequent read precharge command by one, two, or three cycles, depending on said time delay t_{RAS} Add value.

16. The memory controller of claim 14, wherein said time delay t_{RAS} Add value is determined by comparing the three most significant bits of said write precharge scoreboard to a current t_{PPcnt} value.

17. The memory controller of claim 14, wherein a time delay t_{RAS} Add value of one is added to a subsequent read precharge command if the issuance of a read command will cause a subsequent read precharge command to collide with a write precharge command.

18. The memory controller of claim 17, wherein said time delay t_{RAS} Add value becomes a two if the issuance of a second read command will cause an associated second read precharge command to collide with the write precharge command.

19. The memory controller of claim 18, wherein said time delay t_{RAS} Add value becomes a three if the issuance of a third read command will cause an associated third read precharge command to collide with the write precharge command.

20. The memory controller of claim 11, wherein said memory controller is an extreme data rate memory controller.

21. An information handling system capable of handling precharge-to-precharge restrictions when issuing precharge commands, said information handling system comprising:
a processor to handle information via execution of one or more of a plurality of instructions;
a memory storage element, coupled to said processor, to store said plurality of instructions; and
a memory controller, coupled to said memory storage element, to delay an issuance of a read precharge command in response to a determination that a timing parameter violation between a preceding write precharge command and said read precharge command is expected, said memory controller comprising
a write precharge scoreboard to indicate, upon initiation of a write operation corresponding to said preceding write precharge command, a location of said preceding write precharge command from a timing standpoint, and further to indicate whether or not a timing parameter violation between said preceding write precharge command and said read precharge command is expected.
